(19) United States
(12) Patent Application Publication
(10) Pub. No.: US 2013/0277766 A1
(43) Pub. Date: Oct. 24, 2013

(54) MULTIPLE HIGH-K METAL GATE STACKS IN A FIELD EFFECT TRANSISTOR

(71) Applicants: Torben Kelwing, Dresden (DE); Martin Trentzsch, Dresden (DE); Richard Carter, Dresden (DE)

(72) Inventors: Torben Kelwing, Dresden (DE); Martin Trentzsch, Dresden (DE); Richard Carter, Dresden (DE)

(73) Assignee: GLOBALFOUNDRIES INC., Grand Cayman (KY)

(21) Appl. No.: 13/453,596

(22) Filed: Apr. 23, 2012

(51) Int. Cl. H01L 29/78; H01L 21/28

(52) U.S. Cl. 257/411; 438/591; 257/E21.177; 257/E29.255

(57) ABSTRACT

When forming sophisticated high-k metal gate electrode structures, the threshold voltage characteristics are adjusted on the basis of a well-established high-k dielectric material with an appropriate layer thickness, for instance by incorporating an appropriate metal species. Thereafter, further high-k dielectric materials may be deposited, typically with a greater dielectric constant, so as to define the final CET and physical thickness.

### BACKGROUND OF THE INVENTION

1. Field of the Invention

Generally, the present disclosure relates to integrated circuits including advanced transistor elements that comprise complex gate electrodes structures based on a high-k gate dielectric and a metal-containing electrode material.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors, wherein, for many types of complex circuitry, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed between to the highly doped regions. In a field effect transistor, the conductivity of the channel region, i.e., the drive current capability of the conductive channel, is controlled by, among other things, a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially affects performance of MOS transistors.

Presently, the vast majority of integrated circuits are based on silicon due to its substantially unlimited availability, the well-understood characteristics of silicon and related materials and processes and the experience gathered during the last 50 years. Therefore, silicon will likely remain the material of choice for future circuit generations produced by volume production techniques. One reason for the dominant role of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes as are required, for example, during anneal cycles to activate dopants and to cure crystal damage without sacrificing the electrical characteristics of the interface.

For the reasons pointed out above, in field effect transistors, silicon dioxide is preferably used as a base material for a gate insulation layer that separates the gate electrode, frequently comprised of polysilicon and/or metal-containing materials, from the silicon channel region. In steadily improving device performance of field effect transistors, the length of the channel region has continuously been decreased to improve switching speed and drive current capability. Since the transistor performance is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length requires an increased capacitive coupling to avoid the so-called short channel behavior during transistor operation. The short channel behavior may lead to an increased leakage current and may strongly influence the threshold voltage. Aggressively scaled transistor devices with a relatively low supply voltage and thus reduced threshold voltage may suffer from an exponential increase of the leakage current, since enhanced capacitive coupling of the gate electrode to the channel region is required, which has been typically accomplished by reducing the thickness of the silicon dioxide layer. For example, a channel length of approximately 80 nm may require a gate dielectric made of silicon dioxide as thin as approximately 1.2 nm. Hence, the relatively high leakage current caused by direct tunneling of charge carriers through an ultra-thin silicon dioxide gate insulation layer may reach values for an oxide thickness in the range or 1-2 nm that may not be compatible with requirements for performance driven circuits, even if only transistors in speed critical paths are formed on the basis of an extremely thin gate oxide.

Therefore various approaches have been proposed in order to implement a sufficient physical thickness of the gate dielectric material, which is appropriate to keep the leakage currents at an acceptable level, while on the other hand providing a high effective capacitance. Since any well-established treatments of a silicon oxide base material may no longer provide the required increase of the effective capacitance at an acceptable level of leakage currents, it has been proposed to replace at least a significant portion of the well-established oxide-based gate material with alternative dielectric materials having a high dielectric constant, which are typically referred to as high-k dielectric materials and which have a dielectric constant of 10.0 and higher. In many sophisticated approaches for forming gate electrode structures with increased capacitive coupling, thereby enabling a further scaling of the gate length, hafnium-based dielectric materials, such as hafnium oxide and the like, have been identified as appropriate candidates in terms of relatively high dielectric constant with acceptable conduction band offset when formed on a silicon dioxide material. Consequently, a plurality of integration schemes have been developed in order to provide gate electrode structures with a gate length of 40 nm and significantly less without unduly increasing the static power consumption caused by leakage currents, as discussed above. On the other hand, the hafnium-based high-k dielectric materials may require a specific treatment during the manufacturing process so as to not unduly alter material characteristics, which in turn may significantly affect the finally obtained transistor characteristics. For this reason, complex manufacturing strategies have been developed in which the gate dielectric layer including the high-k dielectric material may be implemented in a very advanced manufacturing stage, i.e., after completing the basic transistor configuration and after any high temperature processes, wherein, however, a placeholder gate electrode structure has to be provided during the previous processing, which thus requires the removal of the placeholder materials and the deposition and patterning of the sophisticated gate dielectric material, which in turn may result in a highly complex manufacturing sequence including sophisticated lithography and patterning strategy on the basis of a complex device topography.

In other very promising approaches, the gate electrode structures may be formed in an early manufacturing stage by providing the high-k dielectric material in combination with an appropriate metal-containing electrode material in order to adjust the desired transistor characteristics in terms of work function of the sophisticated gate electrode structure and threshold voltage of the transistor. That is, important device characteristics may be determined on the basis of the high-k dielectric material in combination with an appropriate metal-containing electrode material in an early manufacturing stage, while the remaining patterning of the gate electrode structure may be based on well-established process techniques using materials, such as silicon, silicon/germanium and the like, in combination with appropriate patterning techniques, which are slightly adapted with respect to the presence of a high-k dielectric material and a metal-containing electrode material formed below the standard silicon or silicon/germanium material. During the further processing, a sensitive material, i.e., the high-k dielectric material and the metal-containing electrode material, may be reliably encapsulated so as to substantially avoid undue exposure to reactive process atmospheres, such as wet chemistries of clean processes, oxygen-containing atmospheres and the like. To this end, typically, protective thin sidewall spacers or liners may be provided, for instance in the form of a dense silicon nitride material and the like, which are typically preserved throughout the entire process sequence in order to not unduly shift electronic characteristics of the previously established adjustments with respect to work function and thus threshold voltage.

In some very promising approaches, efficient techniques have been developed so as to adjust and stabilize the characteristics of the sophisticated gate electrode structure for different types of transistors by incorporating an appropriate work function metal species into the lower portion of the sophisticated gate electrode structures. For example, in some of these approaches, a work function metal species, such as aluminum for P-type transistors and lanthanum for N-type transistors, may be incorporated into the gate dielectric material on the basis of appropriate heat treatments, wherein the respective metal species may be diffused from a sacrificial diffusion layer into the underlying gate dielectric material. In this respect, US published patent application 2010/0327373, the entire disclosure of which is incorporated herein by reference, describes a highly efficient technique and semiconductor devices in which different work function metal species may be incorporated into the respective gate dielectric materials by a diffusion process. That is, after providing a dielectric base layer, for instance in the form of a silicon dioxide based material, and after forming thereon the hafnium oxide based high-k dielectric material with a thickness that provides sufficient physical blocking characteristics in terms of leakage currents, while also providing a desired high capacitance, respective metal layers in combination with appropriate cap layers are provided so as to provide one type of metal species, such as aluminum, above the gate dielectric material of a P-channel transistor, while positioning the other type of metal species, such as lanthanum, above the gate dielectric material of an N-channel transistor. Thereafter, a heat treatment is performed, for instance by using temperatures of 800° C. and higher, in order to drive the respective metal species into the high-k dielectric material and possibly to the interface of the base dielectric material, wherein a corresponding concentration of the respective metal species may be adjusted by parameters such as the thickness of the corresponding diffusion layers, the thickness of optional cap layers provided between the gate dielectric material and the diffusion layer and the like for a given set of parameters of the heat treatment. Thereafter, the cap layers and diffusion layers are removed and a common substantially uniform metal-containing electrode material is deposited, followed by the deposition of further electrode materials, such as silicon, silicon/germanium and the like. Thus, an appropriate capacitance equivalent thickness (CET) with respect to conventional silicon oxide materials of 1.2 nm and less may be achieved, while nevertheless the actual physical thickness is significantly greater, for instance approximately 2-3 nm in sophisticated transistors, thereby maintaining the resulting leakage current levels at an acceptable value. On the other hand, the further processing may be continued on the basis of well-established techniques with respect to gate patterning and the like, thereby avoiding very complex gate patterning processes for incorporating a high-k dielectric material in a very advanced manufacturing stage.

Scaling down the electrically effective gate dielectric thickness and maintaining appropriate low gate leakage and threshold voltage adjustability are essential ingredients for advancing to future technology generations. In this respect, hafnium dioxide based high-k dielectrics have been a significant advance in this respect for current sophisticated CMOS techniques requiring a gate length of 40 nm and less. However, a further scaling of the critical device dimensions may require a further reduction of the CET, which may be accomplished by reducing the physical thickness of the hafnium based high-k dielectric, possibly in combination with a further reduction of the thickness of the base oxide material. It turns out, however, that a further reduction of the thickness of hafnium-based high-k dielectric materials may not provide the required transistor characteristics since, in particular, the gate leakage currents and thus the static power consumption may still exceed acceptable levels for future device generations.

In view of these problems associated with a further reduction in thickness of well-established hafnium-based high-k dielectrics, great efforts are presently being made in developing new solutions, wherein, however, any of these solutions has not yet been proven to be compatible with volume production techniques used in sophisticated CMOS process strategies. For example, great efforts are being made in searching for new high-k materials having a higher dielectric constant compared to hafnium-based dielectrics. It is, however, difficult, as discussed above, to find a reasonable material since the resulting band gap or conduction band offset becomes smaller with increasing K values, thereby resulting in increased leakage current of the transistor device. Furthermore, new integration schemes may be required in order to process any such new high-k dielectric material, for instance with respect to interaction with the silicon oxide base material and the like.

In still other approaches, it is attempted to completely eliminate the presence of the silicon dioxide base layer so as to avoid the presence of a dielectric material having a very low dielectric constant. One approach in this respect involves the epitaxial deposition of a corresponding high-k dielectric material directly on the silicon substrate, as proposed by Gottlob et al., IEEE Elec. Dev. Let. 27, No. 10, 2006. However, these approaches are less than desirable with respect to being implemented into volume production techniques since molecular beam epitaxy deposition techniques are required, while at the same time the resulting layers are not very stable at high temperatures. Such materials may thus be considered as viable candidates for replacement gate approaches in which the high-k dielectric material may be provided on the basis of a complex manufacturing regime after any high temperature processes. In other approaches, the silicon dioxide is removed on the basis of appropriate scavenging processes as, for instance, described by Choi et al., Technical Digest of VLSI Symposium 2009, page 138. However, presently there is no degradation approach for CMOS volume techniques known and respective complex new integration schemes may be required.

Furthermore, it has been proposed to apply specific anneal techniques after the deposition of the high-k material and/or after the deposition of the metal-containing electrode material, wherein different process atmospheres, for instance based on argon, nitrogen, oxygen, hydrogen, ammonium, a mixture of hydrogen and nitrogen and the like, are established. Based on any such anneal regimes, the CET may be slightly reduced, for instance on the order of magnitude of 1 Å, without increasing the gate leakage currents, wherein, however, any such reduction is not sufficient to meet the requirements for future device generations or improve device characteristics of presently produced complex semiconductor devices.

In view of the situation described above, the present disclosure relates to process techniques and semiconductor devices in which sophisticated gate electrode structures may be provided, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which gate electrode structures may be provided on the basis of a gate dielectric material that meets the requirements with respect to electrically effective thickness and gate leakage current blocking characteristics, while at the same time providing appropriate work function and thus threshold voltage. To this end, the process of forming the gate dielectric material may include an intermediate test phase for testing and thus defining and setting the threshold voltage characteristics by incorporating a metal species and/or providing an appropriate high-k dielectric material prior to completing the gate dielectric material so as to adjust the final physical thickness. Thereafter, the further processing may be continued by completing the gate electrode structure, which may, in some illustrative embodiments, be a permanent gate electrode structure, while in other cases, if required, a portion of the gate electrode material may be reduced so as to form on the previously provided gate dielectric material any other appropriate gate electrode material.

One illustrative method disclosed herein comprises forming a first gate dielectric layer on an active region of a transistor and diffusing a metal species into the first gate dielectric layer so as to adjust a threshold voltage of the transistor. The method further comprises forming a second gate dielectric layer and an electrode material above the first gate dielectric layer, which includes the metal species. Additionally, the method comprises forming a gate electrode structure on the active region from the gate electrode material and the first and second gate dielectric layers.

A further illustrative method disclosed herein relates to forming a gate electrode structure of a semiconductor device. The method comprises introducing a metal species into a first gate dielectric layer of the gate electrode structure, wherein the first gate dielectric layer comprises a first type of high-k dielectric material. The method further comprises forming a second gate dielectric layer and at least one electrode material layer above the first gate dielectric layer after introducing the metal species. The second gate dielectric layer comprises a second type of high-k dielectric material that differs from the first type of high-k dielectric material. Moreover, the method comprises forming the gate electrode structure from the at least one electrode material layer and the first and second gate dielectric layers.

One illustrative semiconductor device disclosed herein comprises a gate electrode structure formed on an active region of a transistor, wherein the gate electrode structure comprises a gate dielectric layer comprising a first type of high-k dielectric material and a second type of high-k dielectric material. The first type of high-k dielectric material differs from the second type of high-k dielectric material.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device including a transistor having a sophisticated gate electrode structure with a high-k dielectric layer comprising at least two different types of high-k dielectric material, according to illustrative embodiments;

FIG. 1b schematically illustrates an enlarged view of the gate dielectric material formed on a channel region according to the illustrative embodiment of FIG. 1a;

FIG. 1c schematically illustrates a table of results of device characteristics of transistors formed on the basis of sophisticated gate electrode structures compared to high-k metal gate structures according to conventional approaches;

FIGS. 1d-1h schematically illustrate cross-sectional views of the semiconductor device at various manufacturing stages when forming the gate electrode structures as shown in FIG. 1a, according to illustrative embodiments; and

FIGS. 2a-2c schematically illustrate cross-sectional views of a semiconductor device during various manufacturing stages when forming gate electrode structures for different types of transistors based on a dual or multiple high-k dielectric approach, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure is based on the principle that well-known and well-established high-k dielectric materials may be used to define or set the threshold voltage characteristics of sophisticated gate electrode structures, however, while using a physical layer thickness that is appropriate for allowing further overall CET reduction, while, on the other hand, subsequently at least one further gate dielectric layer may be provided to define the final physical thickness of the overall gate dielectric material. On the other hand, the additional one or more gate dielectric layers may not affect the previously adjusted threshold voltage characteristics, which may, for instance, be accomplished by incorporating an appropriate metal species into the underlying previously formed gate dielectric layer. On the other hand, the one or more subsequent gate dielectric layers may be provided on the basis of any appropriate material, such as a high-k dielectric material having a moderately high dielectric constant in order to obtain the desired reduced CET at a reasonable physical thickness, wherein, for instance, any negative effects of the increased K value may essentially be prevented due to the “blocking characteristics” of the previously formed high-k dielectric material. Moreover, established interface characteristics may be preserved, for instance upon forming a well-established base dielectric layer in combination with well-established high-k dielectrics, such as hafnium-based materials, thereby enabling the application of any process technique, for instance process techniques that have been proven very efficient in volume production techniques, for instance as described in the above-referenced US patent application publication 2010/0327373.

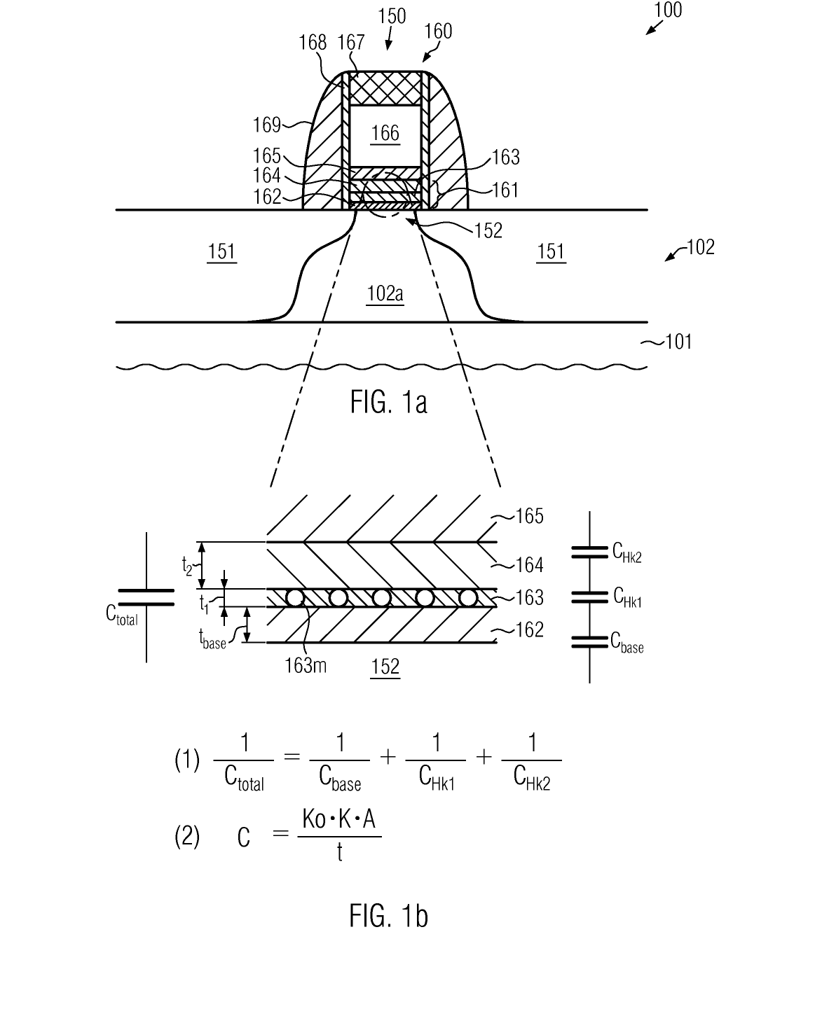

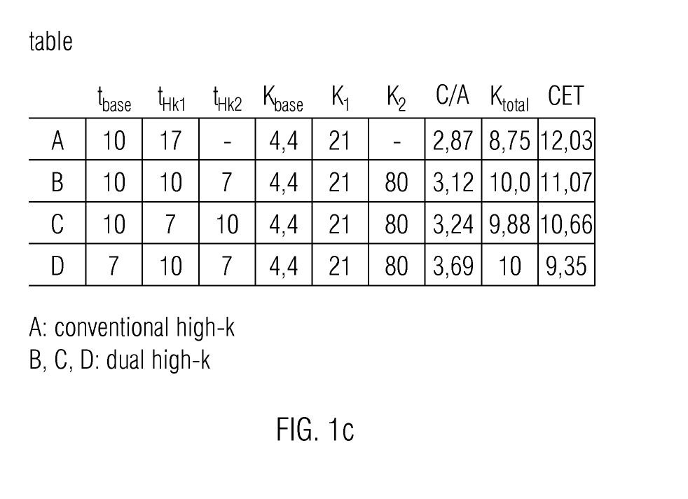

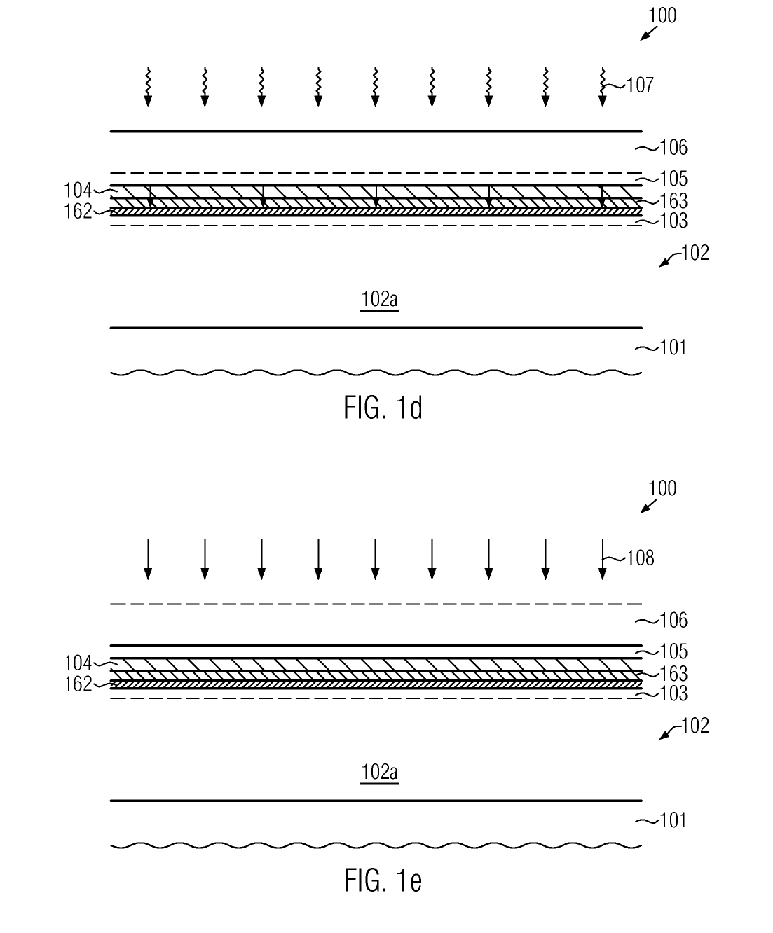

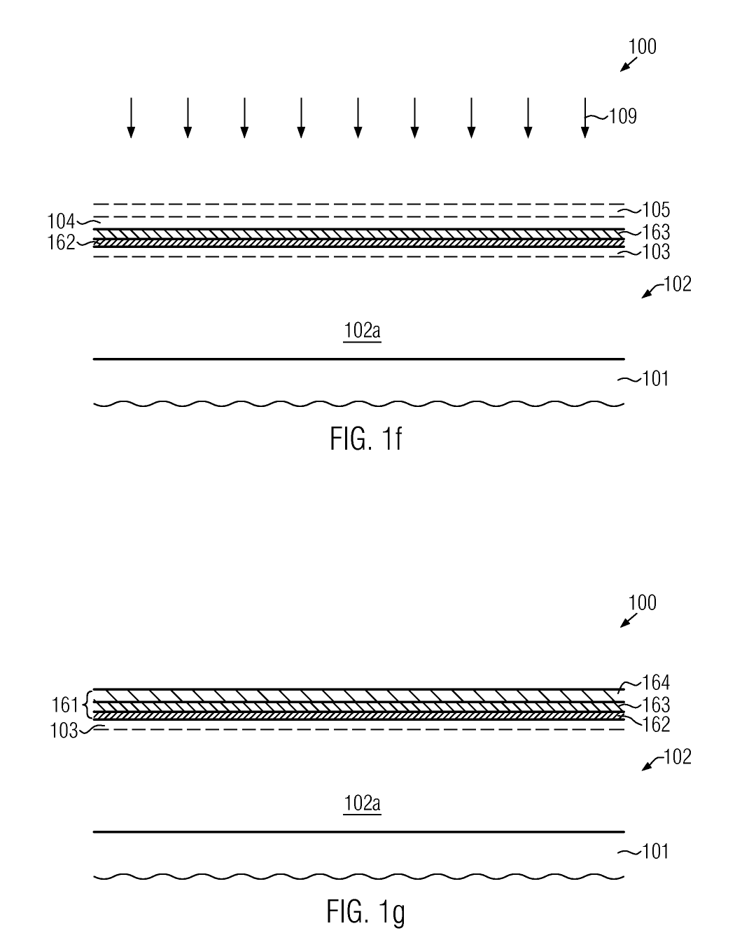

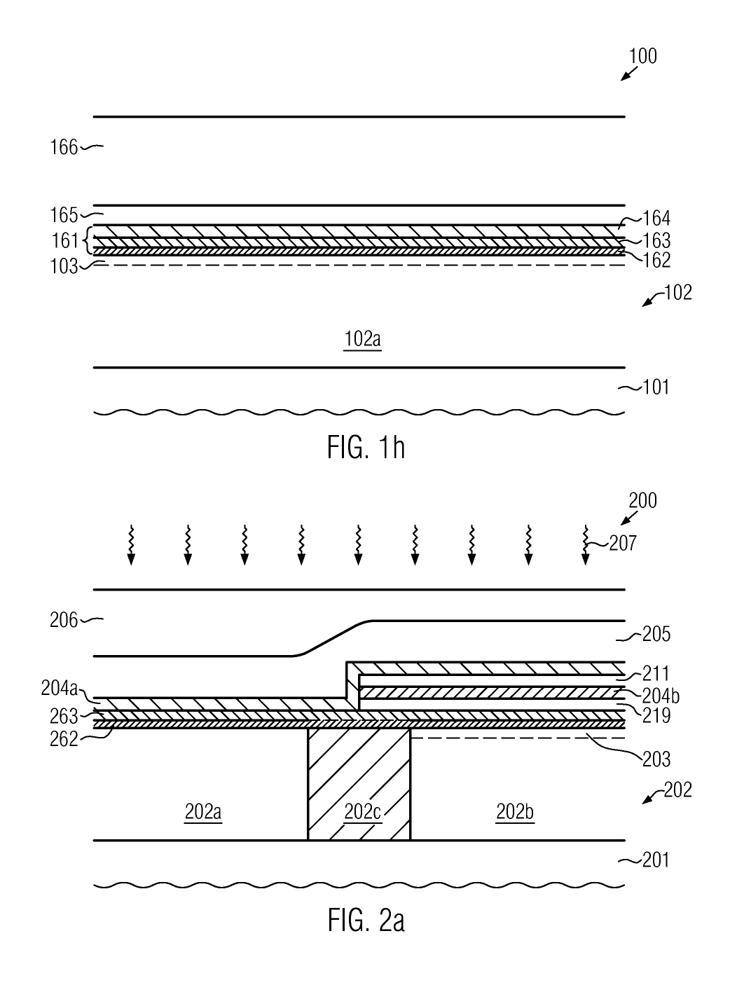

FIG. 1a schematically illustrates a cross-sectional view of a semiconductor device 100 comprising a substrate 101, such as a silicon substrate, a silicon-on-insulator (SOI) substrate, or any other appropriate carrier material for forming thereon a semiconductor layer 102, such as a silicon layer and the like, that is appropriate for forming therein and thereabove a transistor 150. It should be appreciated that the transistor 150 is illustrated as a substantially planar transistor device, while it is to be noted that the principles disclosed herein may also be applied highly efficiently to other transistor architectures, such as three-dimensional transistors or FinFETs and the like. The semiconductor layer 102 may comprise an active region 102a, which is to be understood as a portion of the semiconductor layer 102 comprising an appropriate semiconductor material in which at least one PN junction is to be provided as required for the functioning of the transistor 150. For example, drain and source regions 151 having any appropriate vertical and lateral size and shape may be provided, wherein the polarity type depends on the basic conductivity type of the transistor 150. It should further be appreciated that any other additional dopant species may be present in the active region 102a, as required with respect to the operation of the transistor 150. Furthermore, strained areas may be provided so as to enhance charge carrier mobility, in particular in a channel region 152 of a transistor 150, wherein any such strain-inducing mechanisms are not shown in order to not unduly obscure the principles of the present invention. Similarly, different semiconductor materials, for instance in the form of semiconductor alloys and the like, may be provided, for instance in terms of using a desired type of strain, adjusting other electronic characteristics and the like. Also in this case, any such different semiconductor materials are not shown in FIG. 1a.

The transistor 150 may further comprise a gate electrode structure 160 that is formed on the active region 102a and which comprises a gate dielectric material 161 in combination with one or more electrode materials, such as a metal-containing electrode material 165, for instance provided in the form of titanium nitride and the like, followed by a further electrode material 166, such as a silicon material, a silicon/germanium material and the like. Moreover, in some illustrative embodiments, as shown in FIG. 1a, a further metal-containing material 167, such as a metal silicide or generally a metal/semiconductor compound, may be provided in the gate electrode structure 160 in order to further enhance overall electronic characteristics thereof. Furthermore, a spacer structure 169 may frequently be provided, for instance in the form of any appropriate dielectric materials, such as silicon dioxide, silicon nitride or any combination thereof, wherein, in some illustrative embodiments, an additional liner or spacer structure 168 may be provided so as to laterally protect sensitive materials of the gate electrode structure 160, for instance in the gate dielectric material 161 and the metal-containing electrode material 165, as is also previously discussed. For example, the liner or spacer 168 may be comprised of silicon nitride and the like. In sophisticated applications, a length of the gate electrode structure 160, i.e., in FIG. 1a the horizontal extension of the electrode material 165, may be 40 nm and significantly less, for instance 32 nm and less, in present cutting-edge transistor devices, thereby also requiring a corresponding capacitive coupling of the electrode material 165 to the channel region 152, which in turn may require a corresponding reduction of the capacitance equivalence thickness (CET) on the order of 1.2 nm and less. It should be appreciated that the CET is to be the thickness that would be required by a silicon dioxide material in order to provide a required capacitive coupling. On the other hand, the actual physical thickness has to ensure that any gate leakage currents be within an acceptable level, as is also discussed above. In the embodiment shown, in order to meet these requirements, the gate dielectric material 161 may comprise different gate dielectric layers or sub-layers wherein, in one illustrative embodiment, a dielectric base layer 162 may be provided with an appropriate thickness of 12 Å and significantly less in order to provide well-known interface characteristics with respect to the channel region 152. For example, the dielectric base layer 162 may represent a silicon dioxide-based material, thereby advantageously exploiting the well-understood interface characteristics between a silicon-containing semiconductor material in the channel region 152 and the silicon dioxide material. Furthermore, a gate dielectric material 163 may be provided in combination with the base layer 162, thereby forming a first gate dielectric layer, which may essentially determine the threshold voltage characteristics of the transistor 150, in combination with the remaining transistor configuration, while it should be appreciated that the first gate dielectric layer 163/162 may also be formed by omitting the base layer 162, if considered appropriate. Furthermore, the gate dielectric material 161 may comprise at least one further gate dielectric layer 164, which, in some illustrative embodiments, may be provided in the form of a high-k dielectric material having different characteristics with respect to the layer 163. For example, in some illustrative embodiments, the first gate dielectric layer including the layer 163 may comprise well-established hafnium-based dielectric materials, such as hafnium dioxide, hafnium silicon oxide and the like, with an appropriate thickness which in some illustrative embodiments may be 12 Å and less, while the at least one further dielectric layer 163 may comprise a high-k dielectric material having a significantly higher dielectric constant so as to obtain, in total, an effective dielectric constant that is higher compared to conventional hafnium-based gate electrode structures at the same or a reduced overall physical thickness of the gate dielectric material. For example, the gate dielectric layer 163 may comprise titanium oxide having a dielectric constant of approximately 80, while typical hafnium dioxide base materials may have a dielectric constant K of 21.

FIG. 1b schematically illustrates an enlarged view of the gate dielectric material 161 formed on the channel region 152. As shown, the base layer 162, if provided, may represent any appropriate dielectric material with a thickness t_{base}, which may be selected with respect to device requirements and which may have a value of 10 Å and significantly less. Similarly, the layer 163 has a further part of the first gate dielectric layer defined by the layer 162, if provided, and the layer 163 may be comprised of any appropriate high-k dielectric material, such as a hafnium-based dielectric material of well-understood characteristics with an appropriate thickness t₁ which is appropriate for defining the overall threshold characteristics, i.e., the interaction with the channel region 152, which may be accomplished by incorporating an appropriate work function metal species 163m, for instance in the form of aluminum, lanthanum and the like, depending on the type of transistor under consideration. For example, for a P-type transistor, the metal species 163m may be provided in the form of aluminum within a hafnium-based dielectric material having a thickness of approximately 12 Å and less, wherein concentration of the species 163m may be adjusted during the manufacturing process for forming the gate dielectric material 161, as will be described later on in more detail. Next, the at least one second dielectric layer 164 is formed on the layer 163 and may have any appropriate thickness t₂ so as to define, in combination with the first dielectric layer, i.e., the layer 162, if provided, and the layer 163, an appropriate physical thickness which provides sufficient charge carrier blocking characteristics in order to avoid undue gate leakage currents, as is also previously discussed. Consequently, by selecting an appropriate type of dielectric material for the layer 164, a moderately high dielectric constant may be obtained, however, without significantly affecting the band gap in the channel region 152, since the characteristics thereof are substantially determined by the layers 162 and 163. Furthermore, by appropriately varying the thickness t₂, an appropriate physical thickness may be obtained for given values for t_{base} and t₁.

As illustrated in FIG. 1b, the channel region 152 in combination with the metal-containing electrode material 165 and the gate dielectric material 161 may define a capacitor having a capacitance, indicated by Cₜₒₜₐₗ. This capacitance is defined by a series connection of respective partial capacitance values, indicated by C_{base}, C_{Hk1} and C_{Hk2}. These individual capacitance values are thus substantially determined by the respective dielectric constant K of the corresponding dielectric materials and the corresponding thickness values t_{base}, t₁ and t₂, respectively. Equation 1 shows the expression for calculating the total capacitance from the individual parts defined by the various dielectric materials in the material 161. Furthermore, equation 2 as shown in FIG. 1b shows the general formula for calculating the capacitance value wherein K₀ is the absolute dielectric constant in a vacuum, K is the relative permittivity value, A is the area of the capacitor and t is the corresponding thickness of the dielectric material under consideration. Consequently, by varying the various components of the gate dielectric material 161 in terms of thickness, type of material, and metal species introduced into the layers 162 and/or 163, the desired final characteristics of the gate electrode structure 160 may be efficiently adjusted while at the same time ensuring compatibility with well-established volume production techniques. For example, a significantly increased degree of flexibility is provided by the fact that the threshold voltage adjustment is substantially obtained on the basis of the materials 162 and 163 in combination with the metal species 163m, since thereafter any other appropriate high-k dielectric material may be formed so as to define the final CET without unduly affecting the previously adjusted electronic characteristics, while also avoiding undue interface interactions of high-k dielectric materials with silicon dioxide or a semiconductor material, since these materials may be formed directly on the previously formed high-k dielectric material 163.

FIG. 1c schematically illustrates a table of some illustrative implementations of gate electrode structures, wherein row A represents the device characteristics of a sophisticated high-k metal gate electrode structure formed on the basis of conventional process strategies. That is, in a conventional high-k metal gate electrode structure including a single high-k dielectric material, typical values for the thickness t_{base} and t_{Hk1} may be 10 and 17 Å, respectively. A typical K value for the base dielectric material, for instance provided in the form of a silicon dioxide base material, may be 4.4, while the K value for a hafnium oxide base material may typically be 21. In this case, the capacitance per unit area indicated in the column “C/A” is 2.87, while the total effective K value is 8.75, as indicated in the penultimate column of the table. This results in a CET of 12.03 as indicated in the last column.

On the other hand, rows B, C, D represent respective implementations in which a dual high-k integration regime may be applied, i.e., in addition to the layer 163 comprising a first type of high-k dielectric material, at least one second high-k dielectric material of a different type may be used. For example, the device corresponding to row B has respective values of 10, 10 and 7 for the thickness t_{base}, t_{Hk1} and t_{Hk2}. The relative permittivity values are 4.4 and 21 for the base material and the hafnium-based dielectric material, respectively, while the second high-k dielectric material in the layer 164 (FIG. 1b) is 80 for a typical titanium oxide material. It should be appreciated, however, that this value may significantly depend on the type of high-k material selected. Consequently, the capacitance per unit area is 3.12 and the resulting total K value is 10.0, resulting in a CET of 11.07. It should be appreciated that the significant improvement in CET and the capacitance per unit area is achieved by reducing the thickness t_{Hk1} of the hafnium-based dielectric material compared to the conventional device A and by implementing an additional high-k dielectric material having increased K value, wherein the thickness values are selected so that in total the same physical thickness is obtained as in the conventional case A.

In a further variant as indicated by C, the total physical thickness may remain the same, wherein, however, t_{Hk1} is selected to be less than t_{Hk2} thereby obtaining a capacitance per unit area of 3.24 with a total K value of 9.88, resulting in a CET of 10.66. Consequently, although the same physical thickness is preserved, nevertheless a further reduced CET is obtained.

Finally, the device represented by row D has a reduced thickness of the dielectric base material, for instance 7 Å, while the total thickness of the two types of high-k dielectric materials may be selected to be the same as in the previous examples B and C. In this case, an even further increased capacitance per unit area of 3.69 at a total K value of 10.0 is obtained, thereby resulting in a further reduced CET of 9.35.

It should be appreciated that the above are obtained by applying otherwise identical parameters, for instance in terms of incorporating a specific type of metal species into the layer 163 (FIG. 1b) and the like. As a consequence, an efficient reduction of the CET may be accomplished by introducing at least one further high-k dielectric material of different type compared to the high-k dielectric material that is actually used for setting the threshold voltage characteristics of the transistor under consideration. In this manner, for a given required CET value, for instance corresponding to the CET value of the conventional device A, an increased physical thickness may be provided, for instance, for device B, the thickness t_{Hk1} and/or the thickness t_{Hk2} may be increased so as to increase the CET from 11.07 to 12.03, thereby advantageously increasing the physical thickness, which in turn results in reduced overall gate leakage currents. On the other hand, as illustrated above in the table, for a given physical thickness of the gate dielectric material, a reduction in the CET value may be obtained, as demonstrated by the devices B and C. Furthermore, superior scalability is obtained by further reducing the CET, for instance by reducing the thickness of the base dielectric material and/or the thickness t_{Hk1} and t_{Hk2}, as, for instance, illustrated for the device D with respect to a reduction of thickness of the base dielectric material. It should be appreciated, however, that the above variants are of illustrative nature only and any other combinations of high-k dielectric materials and thickness values, in combination with appropriate metal species that may be incorporated into a lower portion of the gate dielectric material in an intermediate manufacturing phase, may be applied in accordance with the specific requirements to be met by a technology under consideration.

With reference to FIGS. 1d-1h, a manufacturing process will now be described in order to form the semiconductor device 100 as shown in FIGS. 1a and 1b.

FIG. 1d schematically illustrates the device 100 in a manufacturing stage in which a stack of layers may be formed on the active region 102a. It should be appreciated that, in some illustrative embodiments, as already discussed above, the active region 102a may comprise specific semiconductor materials, such as a semiconductor alloy 103, in order to further adjust the threshold characteristics of a transistor device. For example, a silicon/germanium alloy may be provided so as to obtain a desired band gap offset with respect to other types of transistors, if considered appropriate. A corresponding semiconductor alloy may be formed at any appropriate manufacturing stage on the basis of well-established process techniques. Thereafter, the dielectric base layer 162, if required, may be formed by applying well-established techniques, such as oxidation processes and the like, wherein, for instance, a silicon dioxide-based material may be formed on the active region 102a with a desired thickness, wherein, in some illustrative embodiments, the thickness may be reduced prior to continuing the further processing so as to appropriately adjust the thickness of the base layer 162. Thereafter, the layer 163 may be formed, wherein the layers 162, 163 may be considered as a first dielectric layer of the gate dielectric material 161 (FIG. 1a). With respect to the thickness and type of material used, a corresponding selection may be made in accordance with the overall device requirements, as, for instance, discussed above with reference to FIGS. 1b and 1c. Next, a diffusion layer 104 may be formed, for instance in the form of a metal layer, such as an aluminum layer, a lanthanum layer, or any other appropriate material in which the desired metal species is contained that may be caused to diffuse into the layer 163 and possibly into the layer 162 so as to appropriately adjust the threshold voltage characteristics, in a similar manner as is also described in the above-referenced US application. For example, by selecting an appropriate type of material and thickness in combination with process parameters applied during a heat treatment 107, the diffusion process into the layer 163 may be controlled so as to obtain the resulting threshold voltage characteristics. Thereafter, one or more cap layers may be provided, for instance in the form of titanium nitride 105 and silicon 106, wherein it should be appreciated that any other cap materials may be used, depending on the overall process and device requirements. The deposition of these materials may be accomplished on the basis of well-established process techniques. Thereafter, the heat treatment 107 may be performed, thereby initiating diffusion of the metal species 163m (FIG. 1b) into at least the material layer 163. For example, a temperature of 800° C. and higher, such as 900° C. and higher, may be applied for a predetermined time, wherein any appropriate anneal technique may be applied.

FIG. 1e schematically illustrates the device 100 in a further advanced manufacturing phase in which the cap layer 106, for instance comprised of silicon, may be removed during an appropriate removal process 108, which may be performed on the basis of ammonium hydroxide and the like. The optional cap layer 105, which may be provided in the form of titanium nitride and the like, may act as an etch stop material so as to ensure well-defined process conditions.

FIG. 1f schematically illustrates the device 100 during a further removal process 109, which may be performed so as to remove the metal materials from the high-k dielectric material 163. That is, the layers 105, if provided, and 104 may be removed on the basis of appropriate wet chemical chemistries, such as APM-based (ammonium hydrogen peroxide), chemistries, wherein well-established process recipes may be applied. In this case, the layer 163 may efficiently act as etch stop material without suffering from a significant material removal. Consequently, forming the dielectric materials 162, if provided, and the material 163 and adjusting the threshold voltage characteristics thereof by incorporating an appropriate metal species may result in a substantially stable definition of the transistor characteristics prior to forming one or more further gate dielectric materials so as to determine the final physical thickness of the gate dielectric material.

FIG. 1g schematically illustrates the device 100 according to one illustrative embodiment in which the high-k dielectric material 164 may be formed on the material 163 having incorporated therein the metal species, as discussed above, wherein the layer 164 may be comprised of a high-k dielectric material of different type compared to the high-k dielectric material in the layer 163, as discussed above. To this end, any well-established deposition techniques may be applied, for instance atomic layer deposition, chemical vapor deposition and the like, in order to form the layer 164 with a desired material composition and a layer thickness. With respect to selecting an appropriate type of high-k dielectric material and a corresponding thickness, it is referred to a discussion with reference to FIGS. 1b and 1c. It should be appreciated, however, that the dielectric layer 164 may be formed on the basis of two or more different dielectric materials in the form of corresponding sub-layers, if considered appropriate. Thus, after forming the layer 164, the dielectric material 161 is completed so as to have a well-defined physical thickness, while, on the other hand, the threshold voltage characteristics are substantially defined by the layers 162 and 163, as discussed above.

FIG. 1h schematically illustrates the semiconductor device 100 in a further advanced manufacturing stage. As shown, the metal-containing electrode material 165 may be formed above the gate dielectric material 161, wherein any appropriate material and thickness may be used, such as titanium nitride having a thickness of several Å to 100 Å and more, depending on the overall device requirements. Thereafter, a further electrode material, for instance in the form of the material 166, may be provided by well-established deposition techniques. Next, any further material layers (not shown) may be deposited, for instance in the form of silicon nitride, silicon dioxide, amorphous carbon and the like, in combination with any additional layers that are required for performing sophisticated lithography and patterning processes in order to pattern the layer stack, including the materials 161, 165 and 166, into a gate electrode structure of appropriate lateral dimensions. Thereafter, further processes may be continued, for instance, forming a protective sidewall spacer, such as the spacer 168 (FIG. 1a), in order to provide lateral protection of the sensitive gate dielectric material 161 and the material 165. Next, any other process techniques may be applied so as to form the drain and source regions 151, the spacer structure 169, the material 167 (FIG. 1a), wherein any well-established process regime may be applied.

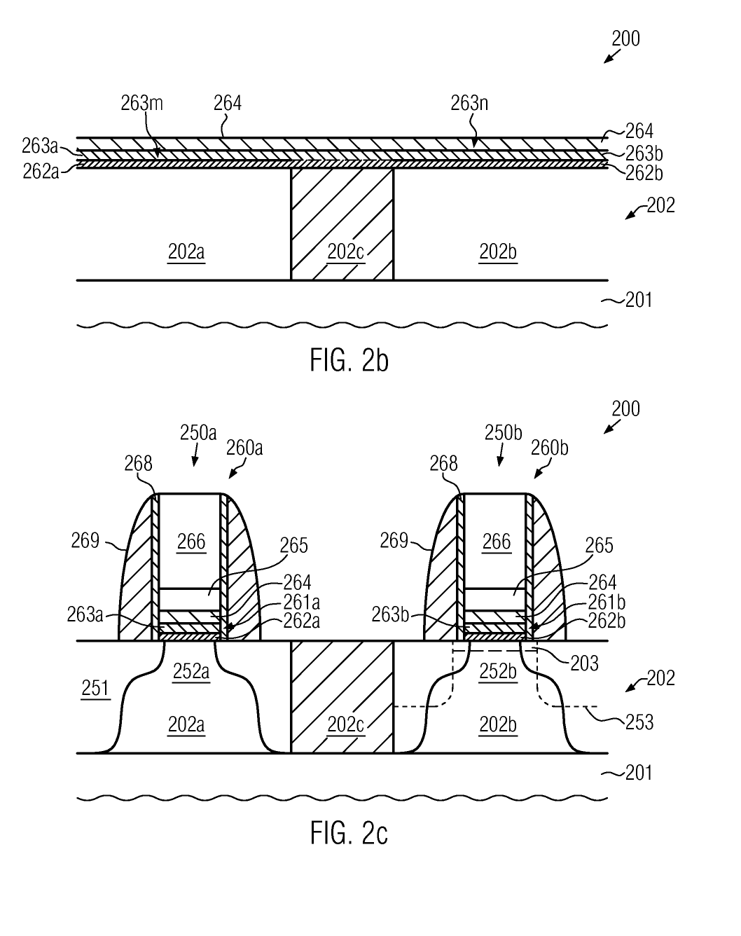

FIG. 2a schematically illustrates a cross-sectional view of a semiconductor device 200 in which gate electrode structures may be formed on the basis of two different gate dielectric materials and may be formed for different transistor types. As shown, the device 200 may comprise a substrate 201, above which may be formed a semiconductor layer 202 comprising a first active region 202a and a second active region 202b, which may be laterally delineated by an appropriate isolation structure 202c, such as a shallow trench isolation and the like. Furthermore, a first gate dielectric layer in the form of a dielectric base material 262 and a high-k dielectric material 263 may be formed on the active regions 202a, 202b, wherein one or both of these regions may comprise additional semiconductor alloys and the like, as indicated by 203, in order to further adapt transistor characteristics as discussed above. For example, the active region 202b may represent a P-type transistor in which a silicon/germanium alloy may be provided as the material 203 in order to obtain a desired band gap offset in combination with a sophisticated gate electrode structure still to be formed on the basis of the materials 262, 263. With respect to the characteristics of the materials 262, 263, the same criteria may apply as previously discussed with reference to the semiconductor device 100. Furthermore, a diffusion layer 204b may be provided above the active region 202b in order to allow the incorporation of an appropriate metal species into the layer 263 and possibly into the layer 262 so as to adjust appropriate threshold voltage characteristics for a transistor still to be formed in and above the active region 202b. For example, a diffusion layer 204b may be provided in the form of an aluminum layer having a thickness of one to several Å. Depending on process and device requirements, an additional spacer layer 219, for instance in the form of titanium nitride having a thickness of one to several Å, may be provided in order to control the diffusion of a metal species into the underlying dielectric materials. It should be appreciated that the layer 219 may also be omitted if a more pronounced diffusion activity into the underlying material 263 may be required for given process parameters of a heat treatment 207. Furthermore, a cap layer 211 may be provided above the diffusion layer 204b, for instance in the form of titanium nitride and the like, having any appropriate thickness so as to substantially decouple a further diffusion layer 204a that may be provided above the layer 211. It should be appreciated, however, that the layer 211 may be omitted, if considered appropriate. On the other hand, the diffusion layer 204a may be formed above the active region 202a so as to be in close proximity to the underlying material 263 in order to ensure efficient diffusion of a metal species, such as lanthanum or any other metal species, into the material 263 so as to obtain desired threshold voltage characteristics for a transistor to be formed in and above the active region 202a. For example, an N-channel transistor may be formed in and above the active region 202a. Furthermore, a cap layer 205, such as a titanium nitride material, followed by a further cap layer 206, may be provided, for instance in the form of silicon and the like.

The layers 262, 263 may be formed in accordance with well-established process techniques, as also described above, and thereafter the optional layer 219 and the diffusion layer 204b in combination with the optional cap layer 211 may be deposited and may be subsequently patterned on the basis of lithography and etch strategies, as are well established in the art, thereby removing these materials from above the active region 202a. Thereafter, the diffusion layer 204a may be deposited, followed by the cap layers 205, 206. Subsequently, the heat treatment 207 may be performed, thereby initiating the diffusion of a metal species from the diffusion layer 204a at least into the layer 263 above the active region 202a, while a corresponding diffusion is substantially prevented by the optional layer 211 and the diffusion layer 204b. On the other hand, the metal species of the layer 204b may be diffused, at least in the layer 263, above the active region 203b. Thereafter, the layer 206 may be removed according to a similar process as discussed above with reference to the device 100, followed by the removal of any metal materials, thereby finally exposing the dielectric material 263 having incorporated therein the corresponding metal species.

FIG. 2b schematically illustrates the device 200 in a further advanced manufacturing stage. As illustrated, dielectric materials 262a, 263a may be formed above the active region 202a, wherein at least the high-k dielectric material 263a may comprise a metal species 263m, such as lanthanum. Similarly, dielectric materials 262b, 263b may be formed on the active region 203b, wherein at least the layer 263b may comprise a metal species 263n, such as aluminum and the like, in order to provide appropriate threshold voltage characteristics. Furthermore, a further dielectric layer 264, for instance comprised of a dielectric material, having a significantly higher dielectric constant compared to the layers 263a, 263b, 262a, 262b, may be provided with any appropriate thickness so as to define the final physical thickness. To this end, any appropriate high-k dielectric material may be formed, such as titanium oxide and the like. It should be appreciated that, with respect to an appropriate selection of high-k dielectric materials, as well as a selection of respective thickness values of these layers, the same criteria may apply as previously discussed above with reference to the device 100. Thereafter, the further processing may be continued as discussed above with reference to the device 100 by forming at least one metal-containing electrode material, possibly in combination with further semiconductor-based electrode material, followed by any further cap layers and sacrificial layers as required for patterning the resulting layer stack.

FIG. 2c schematically illustrates a semiconductor device 200 in a further advanced manufacturing stage. As shown, a first transistor 250a may be formed in and above the active region 202a and may comprise a first sophisticated gate electrode structure 260a. Similarly, a second transistor 250b may be formed in and above the active region 202b and may comprise a second gate electrode structure 260b. The transistors 250a, 250b may comprise respective drain and source regions 251, which laterally enclose corresponding channel regions 252a, 252b, wherein one or more of these regions may include additional measures for adjusting threshold voltage characteristics, such as the semiconductor alloy 203 and the like. The gate electrode structure 260a may comprise a gate dielectric material 261a comprised of at least the layers 263a and 264, possibly in combination with the dielectric base material 262a, wherein at least the material 263a may comprise appropriate metal species, as discussed above. Similarly, the gate electrode structure 260b may comprise a gate dielectric material 261b which includes the layer 263b and 264, possibly in combination with the material 262b, wherein at least the layer 263b may comprise the appropriate metal species, as explained before. Furthermore, the gate electrode structures 260a, 260b may comprise a metal-containing electrode material 265, possibly in combination with a semiconductor-based material 266, wherein these materials are laterally encapsulated by a spacer 268 in combination with a further spacer structure 269. Moreover, as already previously discussed, any further performance enhancing mechanisms may be implemented in one or both of the transistors 150a, 150b, for instance in the form of a strain-inducing material 253, such as a silicon/germanium alloy, a silicon/carbon alloy and the like, as indicated for the transistor 250b by way of example.

Furthermore, it should be appreciated that although the respective metal species in the gate electrode structures 260a, 260b provided for adjusting the threshold voltage characteristics of the corresponding transistors 250a, 250b may be positioned within the layers 263a, 263b, respectively, any such metal species may also diffuse into the corresponding base materials 262a, 262b, while also a certain degree of diffusion may be caused during the further processing of the device 200, for instance during respective high temperature processes, so that a small amount of these metal species may also be present in the layers 264. It should be appreciated, however, that a total concentration of the respective metal species in the corresponding layers 263a, 263b is significantly greater than a respective small metal concentration in the layers 264. Consequently, as already discussed above, the threshold voltage characteristics of the transistors 250a, 250b may be substantially determined during an early manufacturing phase in forming the gate electrode structures 260a, 260b by providing a first gate dielectric layer, while the actual physical thickness and the overall capacitance may be determined after the intermediate threshold voltage adjustment by providing at least one further dielectric material having appropriate material characteristics and thickness.

As a result the present disclosure provides manufacturing techniques and semiconductor devices in which well-established high-k dielectric materials may be used for adjusting the threshold voltage characteristics on the basis of well-established process techniques, however, with an appropriately selected thickness of the high-k dielectric material, typically a reduced thickness compared to conventional strategies, while subsequently one or more further high-k dielectric materials may be used so as to determine the final CET and physical thickness of the gate dielectric material. It should be appreciated that the principles disclosed herein, i.e., the intermediate adjustment of the threshold voltage characteristics, may be combined with any other process technique, for instance processes in which a thickness of the base dielectric material may be reduced prior to forming thereon an appropriate high-k dielectric material. It should further be appreciated that the provision of the high-k dielectric materials in an early manufacturing stage, in combination with the intermediate threshold voltage adjustment, may also be combined with process strategies in which an electrode material may be provided in a later manufacturing stage.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a first gate dielectric layer above an active region of a transistor;
diffusing a metal species into said first gate dielectric layer so as to adjust a threshold voltage of said transistor;
after diffusing said metal species into sad first gate dielectric layer, forming a second gate dielectric layer directly on said first gate dielectric layer that contains said metal species; and
forming a gate electrode structure above said first and second gate dielectric layers.

2. The method of claim 1, wherein forming said first gate dielectric layer comprises forming a high-k dielectric material having a first dielectric constant of 10 or higher.

3. The method of claim 2, wherein forming said first gate dielectric layer further comprises forming a dielectric base material on said active region prior to forming said high-k dielectric material.

4. The method of claim 1, wherein forming said second gate dielectric layer comprises forming a second high-k dielectric material having a second dielectric constant of 10 or higher.

5. The method of claim 4, wherein said second dielectric constant is greater than said first dielectric constant.

6. The method of claim 2, wherein said high-k dielectric material is formed with a first thickness of 12 Å or less.

7. The method of claim 6, wherein said second gate dielectric layer is formed with a second thickness that is different from said first thickness.

8. The method of claim 1, wherein diffusing said metal species into said first gate dielectric layer comprises forming a diffusion layer above said first gate dielectric layer and performing a heat treatment.

9. The method of claim 8, wherein said heat treatment is performed at a temperature of 800° C. or higher.

10. The method of claim 8, further comprising forming a cap layer above said diffusion layer.

11. The method of claim 1, further comprising forming said first gate dielectric layer above a second active region of a second transistor and diffusing a second metal species selectively into said first gate dielectric layer formed above said second active region, wherein said second metal species differs from said metal species.

12. The method of claim 11, further comprising forming a threshold adjusting semiconductor alloy in said second active region prior to forming said first gate dielectric layer.

13. A method of forming a gate electrode structure of a semiconductor device, the method comprising:
introducing a metal species into a first gate dielectric layer of said gate electrode structure, said first gate dielectric layer comprising a first type of high-k dielectric material;
forming a second gate dielectric layer and at least one electrode material layer directly on said first gate dielectric layer after introducing said metal species, said second gate dielectric layer comprising a second type of high-k dielectric material that differs from said first type of high-k dielectric material; and
forming said gate electrode structure from said at least one electrode material layer and said first and second gate dielectric layers.

14. The method of claim 13, wherein introducing said metal species into said first gate dielectric layer comprises forming a diffusion layer above said first gate dielectric layer and performing a heat treatment at a temperature of 800° C. or higher.

15. The method of claim 13, further comprising forming said first gate dielectric layer by forming a dielectric base layer and forming thereon said first type of high-k dielectric material.

16. The method of claim 13, wherein a dielectric constant of said second type of high-k dielectric material is greater than a dielectric constant of said first type of high-k dielectric material.

17. The method of claim 13, wherein forming said first dielectric layer comprises forming a layer of said first type of high-k dielectric material with a thickness of 12 Å or less.

18. A semiconductor device, comprising:
a gate electrode structure formed above an active region of a transistor, said gate electrode structure comprising a gate dielectric layer comprising a first type of high-k dielectric material and a second type of high-k dielectric material, said second high-k dielectric material being formed directly on said first high-k dielectric material, said first type of high-k dielectric material differing from said second type of high-k dielectric material.

19. The semiconductor device of claim 18, further comprising a metal-containing electrode material positioned above said gate dielectric layer.

20. The semiconductor device of claim 19, wherein said first type of high-k dielectric material is provided as a first dielectric sub-layer formed below a second dielectric sub-layer comprising said second type of high-k dielectric material, wherein a concentration of a threshold adjusting metal species in said first dielectric sub-layer is greater than a concentration of said threshold adjusting metal species in said second dielectric sub-layer.

21. A method, comprising:
forming a first high-k dielectric layer above an active region of a transistor;
forming a metal-containing diffusion layer on said first high-k dielectric layer;
after forming said diffusion layer, performing a heat treatment so as to diffuse a metal species from said diffusion layer into said first high-k dielectric layer so as to adjust a threshold voltage of said transistor;
removing said diffusion layer;
after removing said diffusion layer, forming a second high-k dielectric layer directly on said first high-k dielectric layer that contains said metal species; and
forming a gate electrode structure above said second high-k dielectric layer.

22. The method of claim 21, wherein said heat treatment is performed at a temperature of 800° C. or higher.
